(19) United States
(12) Patent Application Publication
(10) Pub. No.: US 2005/0208427 A1
(43) Pub. Date: Sep. 22, 2005

(54) Semiconductor device manufacturing method

(76) Inventors: Katsuya Hayano, Tokyo (JP); Norio Hasegawa, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/030,042

(22) Filed: Jan. 7, 2005

(30) Foreign Application Priority Data
Mar. 16, 2004 (JP) 2004-073739

(51) Int. Cl. G03F 7/00; G03F 7/20

(52) U.S. Cl. 430/311; 430/5; 430/394

(57) ABSTRACT

A semiconductor device manufacturing method which shortens the turnaround time for semiconductor devices. In this method, shading material of resist film lies over a main surface of mask blanks and light-transmitting patterns are made as openings in the shading material. A planarizing film is formed so as to cover the shading material and phase shifters of resist film are formed on the flat top surface of the planarizing film. For exposure, pattern is used. Multiple exposure with two or more exposure areas is made in one chip area, where the exposure areas have patterns equal in shape, size, and arrangement, and phase shifters arranged alternately, so that a line pattern is transferred onto a positive type photoresist film of a semiconductor wafer.

### CLAIM OF PRIORITY

The present application claims priority from Japanese application JP 2004-073739 filed on Mar. 16, 2004, the content of which is hereby incorporated by reference into this application.

### FIELD OF THE INVENTION

The present invention relates to semiconductor device manufacturing technology and more particularly to an exposure technique which uses a phase-shifting mask.

### BACKGROUND OF THE INVENTION

Phase shift technology as superhigh resolution technology is described, for example, in JP-A No. 83032/1994. This patent document discloses a phase-shifting mask which has phase shifters made of resist for drawing with an electron beam, on a mask with a chrome shading pattern (what is called a chrome mask). The document points out that the problem in using resist for drawing with an electron beam as a material for phase shifters is exposure light attenuation due to phase shifter transmittance and discloses the following solution to this problem: two masks with phase shifters reversed in position are prepared and double exposure with these masks is made to compensate for exposure light attenuation. The technique described in this document makes patterning for phase shifters and re-patterning easy and shortens the manufacturing time. In addition, it improves phase shifter patterning accuracy and simplifies the process of compensation for defects.

The present inventors have found that the above technique has the following problems.

Because the shading pattern is made of chrome, the shading pattern is not expected to produce the above effects. This makes it difficult to further shorten the turnaround time for semiconductor devices. If the shading pattern of chrome is to be replaced by a shading pattern of resist, the shading pattern of resist must be thick enough to produce an effect of shielding from exposure light. This means that the aspect ratio of neighboring shading patterns of resist is high. For this reason, if the resist film for phase shifters should be simply stacked on mask blanks, dents would be produced in the top surface of the resist film for phase shifters between neighboring shading patterns of resist, resulting in a thickness unevenness. Consequently, it would be difficult to make phase control in light passing through a light-transmitting area. This problem is not solved by double exposure with two photo masks with phase shifters reversed in position.

### SUMMARY OF THE INVENTION

An object of the present invention is to provide a technique which shortens the turnaround time for semiconductor devices.

The above and further objects and novel features of the invention will more fully appear from the following detailed description and accompanying drawings.

Typical aspects of the invention will be briefly outlined below.

According to one aspect of the present invention, a semiconductor device manufacturing method includes the step of transferring a desired pattern on resist film over a main surface of a semiconductor wafer by reduction projection exposure through a mask, where the mask includes: mask blanks having a first surface and a second surface on its reverse; shading material of resist formed on the first surface of the mask blanks; light-transmitting areas as openings in the shading material of resist; a planarizing film formed on the first surface of the mask blanks so as to cover the shading material; and phase shifters of resist formed on the planarizing film. Here, the planarizing film is buried in openings in the shading material of resist to form the light-transmitting areas so that a phase error in light which passes through the light-transmitting areas is within a tolerance.

A main advantageous effect brought about by the present invention is as follows. Because both shading patterns and phase shifters of the mask are made of resist film, the turnaround time for semiconductor devices is shortened.

### BRIEF DESCRIPTION OF THE DRAWINGS

The invention will be more particularly described with reference to the accompanying drawings, in which:

FIG. 1 is a plan view of a photo mask used in a semiconductor device manufacturing method according to an embodiment of the present invention;

FIG. 2 is a sectional view taken along the line XA-XA of FIG. 1;

FIG. 3 is a sectional view taken along the line XB-XB of FIG. 1;

FIG. 4 is a sectional view of exposure light in an exposure process for an ordinary overlay film shifter type phase-shifting mask;

FIG. 5 is a sectional view of the key part of a mask which has phase shifters in contact with shading material of resist film, where exposure light in an exposure process is illustrated;

FIG. 6 is a sectional view of the key part of the mask of FIG. 1, where exposure light in an exposure process is illustrated;

FIG. 7 is a graph of comparison of thickness reduction of resist film (shading material) with increase in the exposure dose of exposure light, between the presence and absence of a planarizing film;

FIG. 8 shows a light intensity distribution without multiple exposure;

FIG. 9 shows a light intensity distribution with multiple exposure;

FIG. 10 is a focus position versus size difference (0 and π) graph which compares the result of single exposure with that of double exposure;

FIG. 11 is a plan view of a concrete arrangement of phase shifters in an integrated circuit pattern transfer mask;

FIG. 12 is a plan view of a concrete arrangement of phase shifters in an integrated circuit pattern transfer mask;

FIG. 13 is a plan view which schematically illustrates a resist pattern which appears on the wafer as a result of double exposure with light-transmitting patterns shown in FIG. 11 and FIG. 12;

FIG. 14 is a sectional view of the key part of mask blanks in a step of the process of manufacturing the mask of FIG. 1;

FIG. 15 is a sectional view of the key part of mask blanks in a step of the mask manufacturing process which is next to the step of FIG. 14;

FIG. 16 is a sectional view of the key part of mask blanks in a step of the mask manufacturing process which is next to the step of FIG. 15;

FIG. 17 is a sectional view of the key part of mask blanks in a step of the mask manufacturing process which is next to the step of FIG. 16;

FIG. 18 is a plan view of a whole semiconductor wafer in a step of a multiple exposure process;

FIG. 19 is a plan view of the whole semiconductor wafer in a step of the multiple exposure process which is next to the step of FIG. 18;

FIG. 20 is a plan view of the whole semiconductor wafer in a step of the multiple exposure process which is next to the step of FIG. 19;

FIG. 21 illustrates an exposure apparatus used in a process of manufacturing a semiconductor device according to an embodiment of the present invention;

FIG. 22 illustrates main components of the exposure apparatus of FIG. 21;

FIG. 23 illustrates an exposure area for the exposure apparatus of FIGS. 21 and 22;

FIG. 24 illustrates an exposure area for an exposure apparatus different from the exposure apparatus associated with FIG. 23;

FIG. 25 is a plan view of the key part of a semiconductor wafer in a process of manufacturing a semiconductor device according to an embodiment of the present invention;

FIG. 26 is a sectional view taken along the line XC1-XC1 of FIG. 25;

FIG. 27 is a plan view of the key part of the semiconductor wafer in a step of the semiconductor device manufacturing process which is next to the steps of FIGS. 25 and 26;

FIG. 28 is a sectional view taken along the line XC2-XC2 of FIG. 27;

FIG. 29 is a sectional view of the key part of the semiconductor wafer in a step of the semiconductor device manufacturing process which is next to the step of FIG. 28;

FIG. 30 is a sectional view of the key part of the semiconductor wafer in a step of the semiconductor device manufacturing process which is next to the step of FIG. 29;

FIG. 31 is a plan view of the key part of the semiconductor wafer in a step of the semiconductor device manufacturing process which is next to the step of FIG. 30;

FIG. 32 is a sectional view taken along the line XC3-XC3 of FIG. 31;

FIG. 33 is a sectional view of the key part of the semiconductor wafer in a step of the semiconductor device manufacturing process which is next to the step of FIG. 32;

FIG. 34 is a sectional view of the key part of the semiconductor wafer in a step of the semiconductor device manufacturing process which is next to the step of FIG. 33;

FIG. 35 is a sectional view of the key part of the semiconductor wafer in a step of the semiconductor device manufacturing process which is next to the step of FIG. 34;

FIG. 36 is a plan view of the key part of the semiconductor wafer in a step of the semiconductor device manufacturing process which is next to the step of FIG. 35;

FIG. 37 is a sectional view taken along the line XC4-XC4 of FIG. 36;

FIG. 38 is a sectional view of the key part of a mask used in a semiconductor device manufacturing process according to another embodiment of the present invention; and

FIG. 39 is a sectional view of the key part of another area of the mask of FIG. 38.

### DETAILED DESCRIPTION OF THE PREFERRED EMBODIMENTS

Prior to describing the present invention in detail, the terms used in association with embodiments of the invention are defined as follows.

The terms “shading area”, “shading pattern”, “shading material” and “shading” mean provision of an optical characteristic that less than 40% of exposure light cast on an area concerned is transmitted. Generally, the percentage of transmitted light for these terms is in the range of 0% to less than 30%.

The terms “transparent”, “transparent material”, “light-transmitting area” and “light-transmitting pattern” mean provision of an optical characteristic that not less than 60% of exposure light cast on an area concerned is transmitted. Generally, the percentage of transmitted light for these terms is 90% or more.

The term “mask” used in association with embodiments of the present invention is broadly interpreted as including a reticle.

Although preferred embodiments will be described below in different sections or separately on an embodiment-by-embodiment basis, the descriptions are not irrelevant to each other unless otherwise specified. They are, in whole or in part, variations of each other and sometimes one description is a detailed or supplementary form of another. In the preferred embodiments described below, even when a specific numerical figure (quantity, numerical value, amount, range, etc.) is indicated for an element, it is not limited to the indicated specific numerical figure unless otherwise specified or theoretically limited to the specific numerical figure; it should be understood that it may be larger or smaller than the specific numerical figure. It is needless to say that in the embodiments described below, elements (including element steps) are not always essential unless otherwise specified or clearly considered essential theoretically. Likewise, when a shape or position of an element is indicated in the embodiments described below, it is considered that a shape or position which is virtually equal or similar to it is also included, unless otherwise specified or clearly considered not so theoretically. This holds true of numerical figures and ranges as mentioned above. In all the drawings that illustrate preferred embodiments, elements with like functions are designated by like reference numerals; and descriptions of these elements are not repeated.

Next, preferred embodiments of the present invention will be described in detail referring to the accompanying drawings.

### First Embodiment

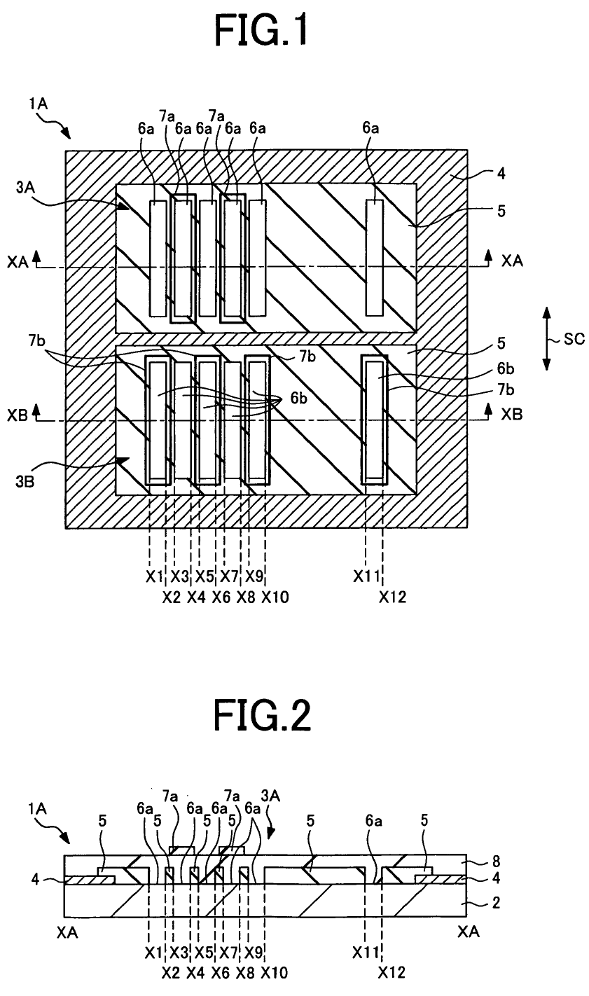

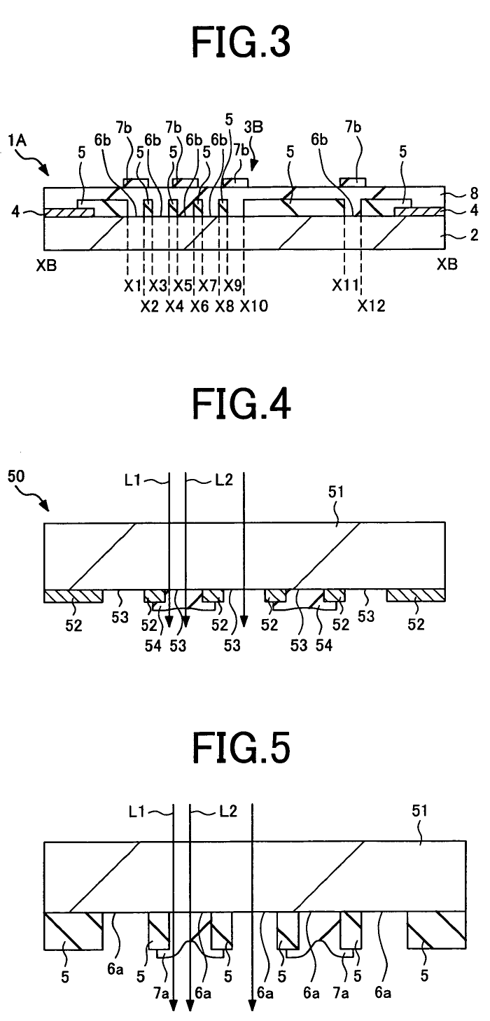

FIGS. 1 to 3 show an example of a photo mask used in a semiconductor device manufacturing method according to the first embodiment of the present invention. FIG. 1 is a plan view of a whole photo mask 1A according to the first embodiment. FIGS. 2 and 3 are sectional views taken along the lines XA-XA and XB-XB respectively. FIG. 1 includes hatching to facilitate understanding. FIGS. 1 to 3 show coordinates X1 to X12 to facilitate understanding of positional relationship among the figures.

In the first embodiment, the mask 1A is an example of a photo mask which is used to transfer, or make an exposure of a line pattern (wiring and electrode pattern) as an integrated circuit pattern. Flat rectangular mask blanks 2 which constitute the mask 1A are, for example, made of synthetic quartz glass which is transparent to exposure light and the flatness of the whole main surface (first surface) is typically in the range of 0.2 (max) to 0.5 μm (min). For example, two flat rectangular exposure areas 3A and 3B are arranged side by side vertically (in the scan direction SC of an exposure apparatus) as shown in FIG. 1 on the main surface (first surface) of the mask blanks 2. Each of the exposure areas 3A and 3B is an exposure area for a single semiconductor chip (hereinafter called a chip) and these areas are equal in planar shape and size. As will be stated later, in the first embodiment, a desired line pattern is transferred (exposed) on photoresist film of each chip area of a semiconductor wafer (hereinafter called a wafer) by double exposure with the exposure areas 3A and 3B.

Two different types of shading materials 4 and 5 are formed on the main surface of the mask blanks 2. The shading material 4 is, for example, made of metal film such as chromium (Cr) film or a laminate of chromium and chromium oxide and lies around the exposure areas 3A and 3B. The shading material 5 is, for example, made of resist film and lies inside the exposure areas 3A and 3B. The shading material 5 should have an optical density of 3 or OD3 (almost equal to the shading rate of 100 nm thick chromium film) or more than OD3 (namely, shading rate at which 1/1000 or not more than 1/1000 of incident exposure light on the mask 1A is transmitted). From this viewpoint, the resist film for the shading material 5 may be polyvinyl phenol resin or the like. The thickness of the shading material 5 is much larger than that of the shading pattern 4 (metal film) so that the above requirement for shading is met. It is, for example, 650 nm or so. The exposure light shading performance may be improved by adding a pigment or the like to the resist film which constitutes the shading material 5.

Plural light-transmitting patterns 6a and 6b which transmit light are provided in the exposure areas 3A and 3B for transfer of a line pattern. These light-transmitting patterns 6a and 6b are formed by making openings in parts of the shading material 5. FIG. 1 shows an example that in the exposure areas 3A and 3B there are a zone (left) where light-transmitting patterns are densely arranged and a zone (right) where light-transmitting patterns are sparsely arranged. In the pattern dense zone, there is a concentration of light-transmitting patterns 6a (6b). On the other hand, in the pattern sparse zone, light-transmitting patterns 6a (6b) are sparse and isolated. In this example, there is one light-transmitting pattern 6a (6b) in the sparse zone. However, even if there are two or more light-transmitting patterns, the zone concerned is considered as a pattern sparse zone as far as interference of transmitted light between neighboring light-transmitting patterns rarely occurs.

In the exposure areas 3A and 3B, the light-transmitting patterns 6a and 6b are equal in shape and size. Phase shifters 7a (7b) (hereinafter called shifters) as indicated by bold line are provided in the pattern dense zone of the exposure area 3A (3B) so as to turn light passing through neighboring light-transmitting patterns 6a (6b) by 180 degrees. In other words, the pattern dense zones of the exposure areas 3A and 3B are Levenson type ones that provide a superhigh resolution. In this way, the use of shifters 7a (7b) for light-transmitting patterns 6a (6b) in the pattern dense zone makes it possible to achieve a high resolution due to a phase shifting effect.

In comparison between the light-transmitting patterns 6a in the pattern dense and sparse zones of the exposure area 3A of the mask 1A and the light-transmitting patterns 6b in those of the exposure area 3B, the light-transmitting patterns 6a and 6b are equally arranged and equal in shape and size. The difference is that the shifters 7a of the exposure area 3A and the shifters 7b of the exposure area 3B are reversed, or alternately arranged. In other words, the shifters 7a and 7b are arranged so that when double exposure is made with the exposure areas 3A and 3B, light passing through a given light-transmitting pattern 6a in the exposure area 3A is turned by 180 degrees with respect to light passing through a light-transmitting pattern 6b in the exposure area 3 which corresponds to that pattern 6a, or is in alignment with it on the same plane. In this example, there is no shifter in the pattern sparse zone of the exposure area 3A and there is a shifter in the pattern sparse zone of the exposure area 3B. However, it is also acceptable that no shifters 7a and 7b are provided on light-transmitting patterns 6a and 6b in the pattern sparse zones of the exposure areas 3A and 3B.

The shifters 7a and 7b are considered as overlay film shifters. This is because the shifters 7a and 7b are formed by patterning the resist film on a planarizing film 8 over the main surface (first surface) of the mask blanks 2. When the mask 1A has overlay film shifters, it is far easier to manufacture than when it has slit shifters which must be roofed. The number of steps in the process of manufacturing the mask 1A can be decreased and the time required to manufacture the mask 1A can be shortened. Also the yield of the mask 1A is improved. Particularly, the longer the slit shifter roof is, the more it is effective; however, there is a limitation on the roof length because demand for finer patterns on a wafer is growing and thus the mask 1A pattern tends to be finer and finer. In this sense, the technique in the first embodiment is suitable for very fine patterns because it improves pattern size accuracy without the need for a roof structure. The resist film material for formation of shifters 7a and 7b and its thickness are chosen so that the shifters 7a and 7b are transparent to exposure light. The thickness D of the shifters 7a and 7b is designed to meet the relation of D=λ/(2(n−1) in order to turn transmitted light by 180 degrees, where n denotes refractive index of shifters 7a or 7b with respect to exposure light with a given exposure wavelength and λ denotes an exposure wavelength. From this viewpoint, the resist film material for the shifters 7a and 7b is, for example, polyethylene resin or the like. The thickness of the shifters 7a and 7b is smaller than that of the resist film for the shading material 5 and, for example, in the range of 115-120 nm or so.

The planarizing film 8 covers the shading materials 4 and 5 over the main surface (first surface) of the mask blanks 1. The planarizing film 8 has a function of reducing a level difference attributable to the shading material 5 and its top surface is maintained almost flat. It is most desirable that the top surface of the planarizing film 8 be completely flat. However, the top surface need not be completely flat; it is sufficient that the planarizing film is buried in the openings in the shading material 5 for light-transmitting patterns 6a (6b) in a way to prevent a phase difference in light passing through light-transmitting patterns 6a (6b) covered by shifters 7a (7b) or keep a phase difference within a permissible range. Concretely, a level difference after planarizing should be 50% of the exposure wavelength or less and more desirably 30% or less. The reason for this is as follows.

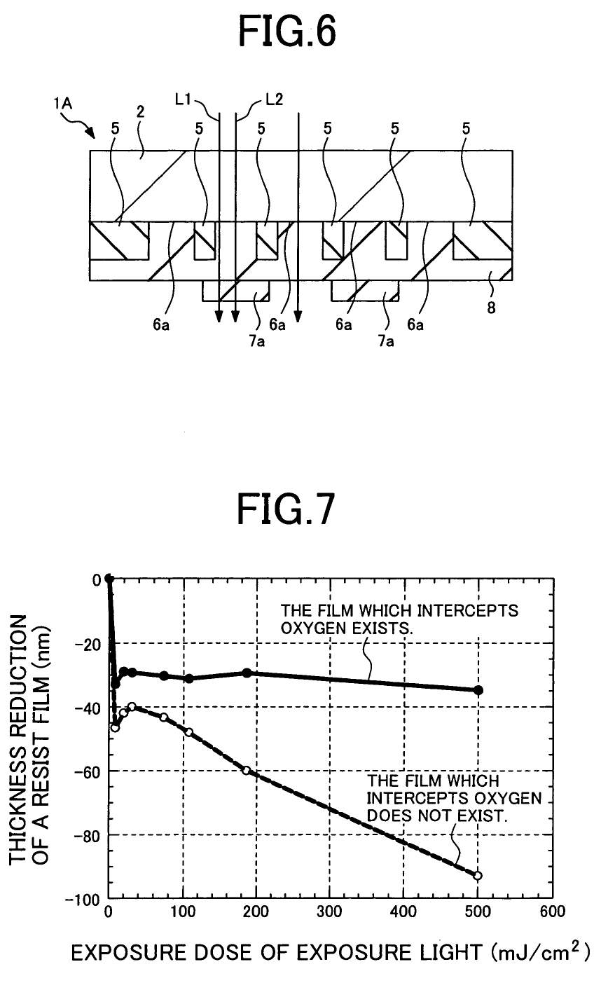

FIG. 4 is a sectional view of the key part of an ordinary overlay film shifter type phase-shifting mask 50. Shading patterns 52 (metal film) and light-transmitting patterns 53 are formed on the main surface of the mask blanks 51. A shifter 54 is located over one of two neighboring light-transmitting patterns 53. Since the shifter 54 is formed over the mask blanks 52 in contact with a shading pattern 52, there may be a small dent in the top surface of the shifter 54 depending on the thickness of the shading pattern 52. For this reason, a phase difference between exposure light L1 and L2 passing through a light-transmitting pattern 53 covered by a shifter 54 may arise. In the case of this phase-shifting mask 50, since the shading pattern is made of metal film and thin (aspect ratio is small), the above problem of phase difference is not so serious. On the other hand, as shown in FIG. 5, if the shading material 5 is resist film, the shading pattern should be far thicker (larger aspect ratio) than the above metal film shading pattern in order for the shading material 5 to provide the required exposure light shading performance. If a shifter 7a should be formed over the mask blanks 2 in direct contact with the shading material 5, the top surface of the shifter 7a would have a large dent due to the thickness of the shading material 5. Hence, a phase difference between exposure light L1 and L2 passing through a light-transmitting pattern 6a covered by a shifter 7a would be large. This problem is not solved even by double exposure with the exposure areas 3A and 3B. By contrast, in the first embodiment, as illustrated in FIGS. 2, 3, and 6, the use of the planarizing film 8 and formation of shifters 7a and 7b over it improve the flatness of the shifters 7a and 7b. This prevents a phase difference in light L1 and L2 passing through a light-transmitting pattern 6a (6b) covered by a shifter 7a (7b) or keeps a phase difference within a permissible range.

Without the planarizing film 8, a level difference attributable to the thickness of the underlying shading material 5 and some pattern density would cause fluctuation in the thickness of the resist film for formation of shifters and thus phase difference fluctuation. Since the thickness distribution of the resist film for formation of shifters over the main surface of the mask blanks 2 corresponds to phase difference distribution, it is important to control the thickness of the resist film. However, it is difficult to control it because of underlying material level difference or pattern density difference. On the other hand, in the first embodiment, the planarizing film 8 improves the flatness of the resist film for formation of shifters 7a and 7b and facilitates patterning of the shifters 7a and 7b. In addition, the thickness uniformity among plural shifters 7a and 7b over the main surface of the mask blanks 1A and the size controllability are improved. Therefore, phase difference fluctuation over the main surface of the mask blanks 1A is reduced. This makes it possible to transfer or make exposures of patterns properly, leading to improvement in the yield and reliability of semiconductor integrated circuit devices.

The planarizing film 8 also has a function of preventing exposure of the shading film 5 to oxygen in the air. This function is used to mitigate or prevent the following problem: if an exposure is made with the shading material 5 exposed to oxygen, the transferred pattern size might change as a result of etching of the shading material 5 caused by a light ashing phenomenon. Another possible approach to minimizing or preventing such etching of the shading film 5 is to make the surroundings of the mask an inert atmosphere (for example, nitrogen atmosphere) during exposure. However, that approach needs a substantial modification to the exposure apparatus and involves a problem about working safety. By contrast, in the first embodiment, in which the shading material 5 is covered by the planarizing film 8, the possibility of etching of the shading material 5 in the exposure process is minimized or prevented and thickness fluctuation of the shading material 5 is reduced or prevented with no need for modification to the exposure apparatus and no working safety problem. In short, the light resistance of the shading material 5 is improved. FIG. 7 is a graph of comparison of thickness reduction of a resist film (shading material 5) with increase in the exposure dose of exposure light, between the presence and absence of the planarizing film (film which intercepts oxygen).

As indicated by the dotted line, without the planarizing film 8, exposure light causes reaction between oxygen and the resist film, resulting in thinning of the resist film. As indicated by the solid line, with the planarizing film 8 (film which intercepts oxygen), thinning of the resist film (shading material 5) is drastically reduced. Although it is most desirable for the planarizing film 8 to perfectly intercept oxygen, it need not always intercept oxygen perfectly. The lower the oxygen concentration is, the smaller the reaction between oxygen and the resist film is and the longer the mask service life is.

The thickness of the planarizing film 8 which meets the above condition may be in the range of 600-700 nm, preferably 800 nm or so. The planarizing film 8 is also transparent to exposure light and made of an inorganic material (water-soluble) or an organic material. The inorganic material for the planarizing film 8 may be polyvinyl alcohol (PVA), polyvinyl phenol (PVP) or the like. If the material is inorganic, the solvent used is water and the underlying resist film (shading material 5) does not deteriorate (mixing does not occur) and its coatability is good. The organic material for the planarizing film 8 may be silicon (Si) resin such as polyethylene resin or polymethyl siloxane. This type of organic material provides high mechanical resistance. Generally, organic film easily thickens and its flatness is high. In addition, organic materials intercept oxygen more effectively than inorganic materials.

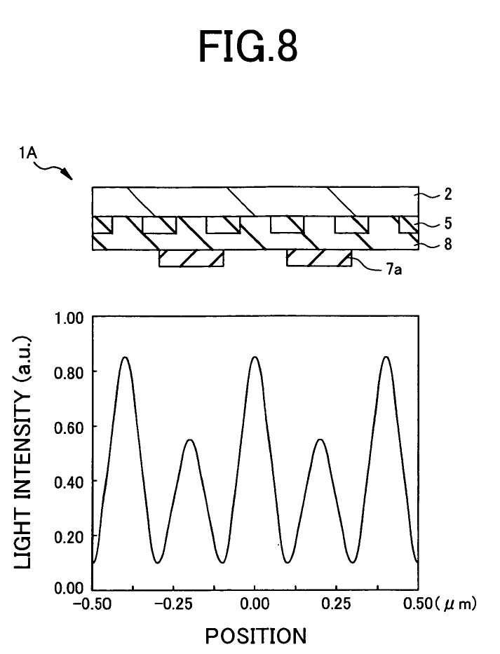

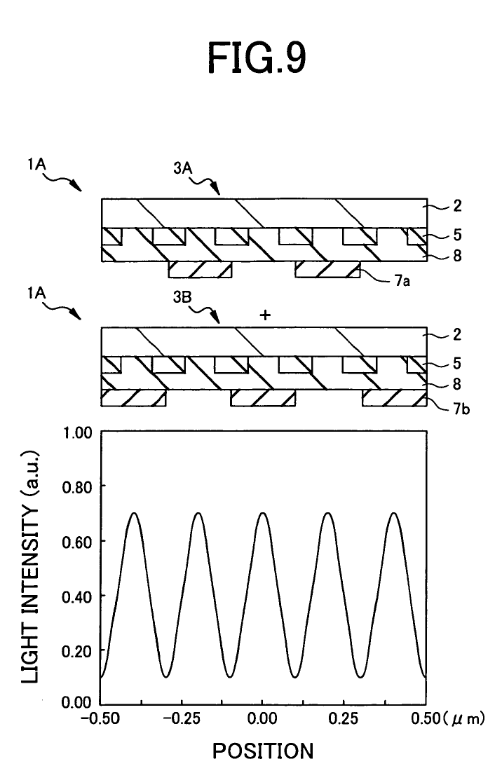

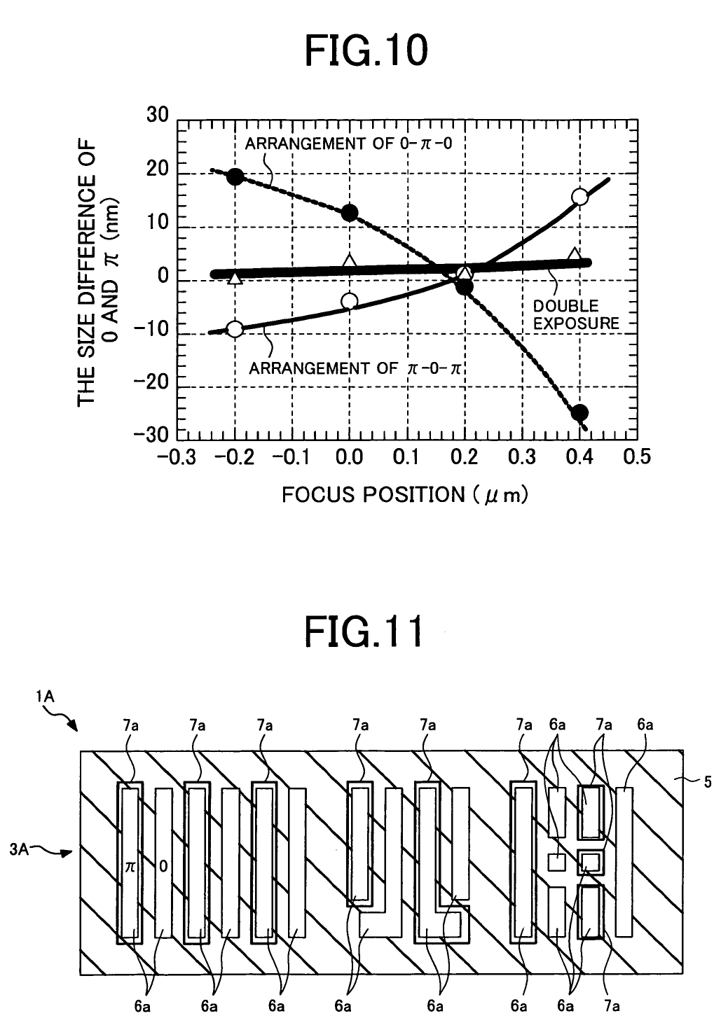

In the first embodiment, as an exposure process is continued, the material of the shifters 7a and 7b reacts with oxygen around the mask 1A (light ashing) and the shifters 7a and 7b are etched and thus become thinner than required. The result is change in phase difference. Hence, in the first embodiment, double exposure is made using the exposure areas 3A and 3B where the shifters 7a and 7b are alternately arranged as mentioned above. This gives more tolerance in phase absolute accuracy (phase error tolerance). For example, the permissible phase angle error range may be wider than ±5 degrees (phase shift angle may be larger than 185 degrees or smaller than 175 degrees). Therefore, the thickness accuracy requirement of the shifters 7a and 7b is eased. For example, if a phase difference of 30 degrees occurs and 0.2 μm defocusing is done, light intensity peaks differ depending on the presence or absence of shifters 7a unless double exposure is made, as shown in FIG. 8. On the other hand, when double exposure is made, the shifters 7a and 7b work to eliminate imbalance in light intensity peaks, as shown in FIG. 9 and a balanced light intensity distribution is achieved. FIG. 10 is a focus position versus size difference (of 0 and π) graph which compares the result of single exposure with that of double exposure. The graph shows that for double exposure, the focus position is stable regardless of the size difference of 0 and π. This implies that even when the resist film (shifters 7a and 7b) changes in thickness as a result of being etched by exposure light, double exposure with the above alternately arranged phase shifters guarantees a satisfactory phase shifting effect. Therefore, when the above double exposure method is employed, exposure through the mask 1A in the first embodiment is performed without the need for special attention to exposure light dose and light resistance for the mask 1A. In addition, when the etching rate for the planarizing film 8 is almost the same as that for the shifters 7a and 7b, the relation between phase angles 0 and 180 degrees for light passing through the light-transmitting patterns 6a is kept almost constant.

In the first embodiment, even if the phase absolute accuracy is low, double exposure makes it possible to achieve the same resolution as with a phase difference of 180 degrees and thus improves size accuracy in patterns transferred onto the wafer (transfer patterns).

Because the thickness accuracy requirement of the shifters 7a and 7b is eased, the ease of manufacturing the mask 1A is remarkably increased and consequently the yield in the manufacture of the mask 1A is improved. Hence the cost of the mask 1A is reduced. Particularly, in the first embodiment, in which exposure areas 3A and 3B for double exposure are provided in different places on the same plane of the same mask 1A, the shifters 7a and 7b are more uniform in terms of their thickness and errors on the main surface of the mask blanks 2 than when exposure areas 3A and 3B are provided in different masks. Hence, the mask 1A is more easily manufactured while the phase absolute accuracy is kept relatively high. Besides, since a single mask 1A is used for double exposure, the throughput is better than when exposure areas 3A and 3B are provided in different masks. It is also acceptable that after an exposure is made through a mask having an exposure area 3A only, the mask is replaced by a mask having an exposure area 3B only and another exposure is made through it for double exposure. This method is useful when the chip size is large and it is impossible for a mask to have both exposure areas 3A and 3B.

With single exposure, since the intensity of light passing through light-transmitting patterns 6a and 6b covered by shifters 7a and 7b lowers, transferred patterns may differ in size depending on the presence or absence of shifters 7a or 7b. On the other hand, in this embodiment, an area is exposed to both light passing through a light-transmitting pattern 6a (6b) covered by a shifter 7a (7b) and light passing through a light-transmitting pattern 6a (6b) not covered by a shifter 7a (7b) so the light intensities of exposed areas are averaged. In short, light intensity imbalance is eliminated and a uniform light intensity distribution is achieved. This reduces or prevents transferred pattern size fluctuation and improves transferred pattern size accuracy. Hence, the characteristics and reliability of semiconductor integrated circuit devices are improved.

According to the first embodiment, random defects in exposure areas 3A and 3B are averaged or removed by multiple exposure and transfer of defects of the mask 1A is reduced or prevented. Also, the transfer limitations in which defects of the mask 1A are not transferred can be expanded. Consequently, size defects which have been so far unignorable are ignorable. For example, defects of less than 0.4 μm of the mask 1A can be ignored and the permissible defect size range in defect inspection of the mask 1A can be widened. This makes defect inspection and defect correction of the mask 1A easier and it becomes easier to manufacture the mask 1A. In addition, the effects of aberration averaging and mask 1A size distribution averaging contribute to improvement in transferred pattern size accuracy. Therefore, the characteristics and reliability of semiconductor integrated circuit devices are improved.

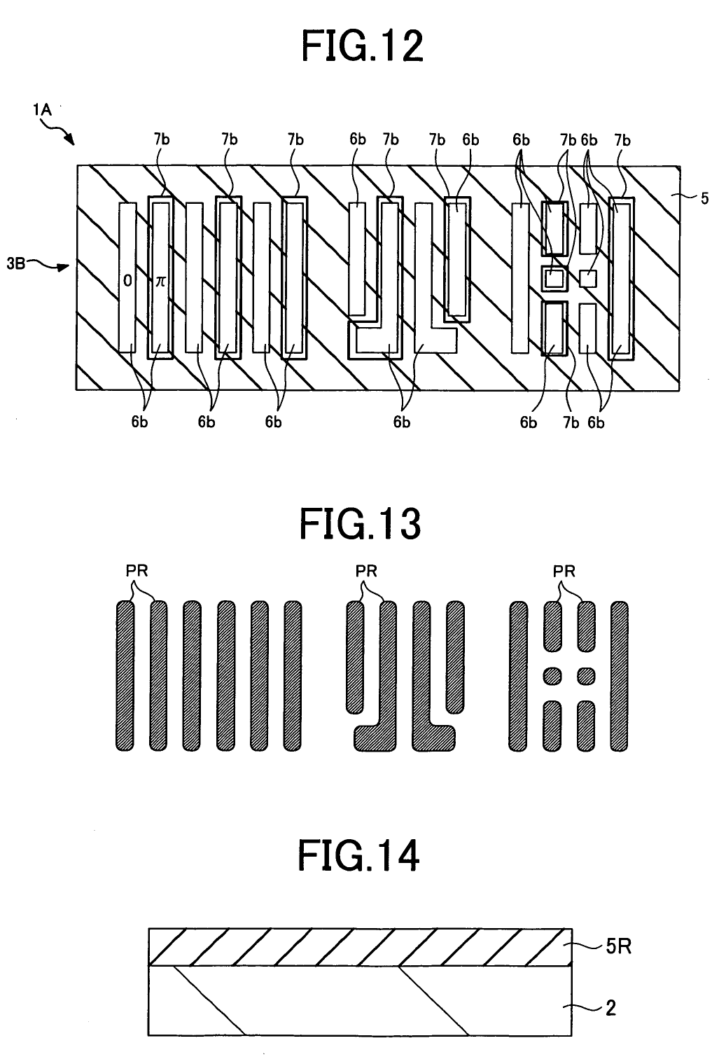

FIGS. 11 and 12 show concrete examples of shifters 7a and 7b over the mask 1A for transfer (exposure) of integrated circuit patterns, respectively. The arrangement of shifters 7a and that of shifters 7b are reversed or alternate so that the light-transmitting patterns 6a (FIG. 11) and the light-transmitting patterns 6b (FIG. 12) are used for double exposure. FIG. 13 schematically illustrates a photoresist film PR pattern which appears on the wafer as a result of double exposure with light-transmitting patterns 6a (FIG. 11) and 6b (FIG. 12).

The number of exposure areas over a photo mask 1A is not limited to 2. There are other light-transmitting patterns such as mask alignment marks and measuring marks in the shading area (of the shading material 4) around the exposure areas 3A and 3B. Patterns which are not essentially constituent elements of an integrated circuit, such as alignment mark patterns, mark patterns used for alignment testing or mark patterns used for testing of electrical characteristics, may be formed inside the exposure areas 3A and 3B. Even in the first embodiment, optical proximity correction (OPC) is necessary as usual. For example, size correction is needed with regard to parameters such as the distance from an object pattern to an adjacent pattern, the width of the adjacent pattern, and presence of a phase shifter.

One example of a method of manufacturing the mask 1A according to the first embodiment will be described referring to FIGS. 14 to 17. FIGS. 14 to 17 are sectional views showing the key part of the mask 1A in the manufacturing process.

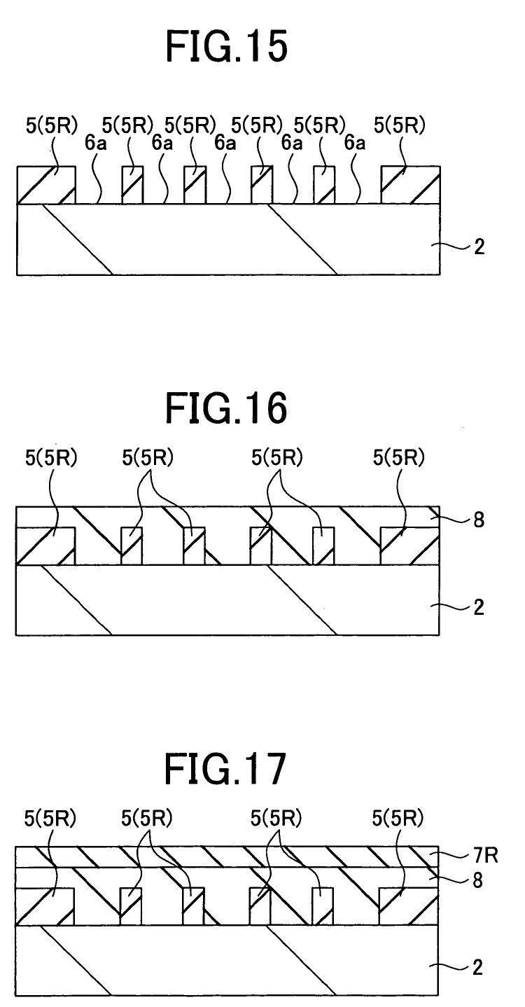

As illustrated in FIG. 14, after resist film 5R is coated by rotary coating or a similar technique, baking is done to remove the solvent in the resist film 5R. It is desirable that the thickness of the baked resist film 5R be in the range of 600-700 nm or so if KrF excimer laser light (wavelength 248 nm) is used as exposure light or in the range of 200-300 nm or so if ArF excimer laser light (wavelength 193 nm) is used. The optimum thickness of the resist film 5R depends on the value of n or k of the resist film 5R. Then, patterns of the shading material 5 are formed by exposure with an electron beam or the like, development, and baking, as illustrated in FIG. 15. In the figure, the openings (parts where the shading material 5 is removed) are light-transmitting patterns 6a.

Then, as illustrated in FIG. 16, a planarizing film 5 is made over the main surface (first surface) of the mask blanks 2 so as to cover the shading material 5 by rotary coating or a similar technique. The rotary coating technique flattens the top surface of the planarizing film 8 by surface tension. In addition, the planarizing film 8 can be dried during rotation. Instead, it may be dried after rotary coating. The speed of rotation of the wafer stage for rotary coating may be 1500 rpm or so. Materials for the planarizing film 8 are divided into an inorganic material group (PVA, PVP, etc) and an organic material group (polyethylene resin, silicon resin, etc). When an inorganic material is chosen for the planarizing film 8, mixing with the resist film 5R (shading material 5) hardly occurs and the temperature of baking after patterning of the shading material 5 or formation of the planarizing film 8 need not be so high but should be in the range of 100-120° C., or a temperature sufficient for dehydration. By contrast, when an organic material is chosen for the planarizing film 8, mixing with the resist film 5R (shading material 5) easily occurs and the temperature of baking after patterning of the shading material 5 or formation of the planarizing film 8 should be higher than the above baking temperature for dehydration, for example, in the range of 140-180° C., or a temperature sufficient for curing. The thickness of the baked planarizing film 8 should be at least in the range of 600-700 nm, preferably 800 nm or so.

Next, after resist film 7R for shifters is coated on the planarizing film 8 by rotary coating or a similar technique as illustrated in FIG. 17, shifters 7a and 7b of the resist film 7R are formed by patterning through exposure with an electron beam or the like, development, and baking, as illustrated in FIGS. 1 to 3. A mask 1A is thus produced.

According to the first embodiment, since the resist film 7R is coated on the planarizing film 8, the uniformity in the thickness of the resist film 7R on the main surface of the mask blanks 2 is improved. The thickness of the resist film 7R may be 130 nm just after coating or in the range of 115-120 nm just after baking. The resist film 7R should be a negative type film. This is because the areas where shifters 7a and 7b are formed are smaller than other areas on the main surface of the mask blanks 2 and the required time for exposure of the areas for shifters 7a and 7b with an electron beam is shorter than the required time for exposure of the other areas. In other words, when negative type resist film 7R is used, the required exposure time is shorter and the time required to manufacture the mask 1A is shorter than when positive type one is used.

As discussed so far, according to the first embodiment, all the patterns in the exposure areas 3A and 3B of the mask 1A can be made of resist film. This means that it is possible to make patterns in the exposure areas 3A and 3B of the mask 1A with no etching process. Due to the absence of an etching process, foreign matter is reduced and the result is improvement in the mask 1A yield. Moreover, the mask 1A has fewer defects and the turnaround time (TAT) for the mask 1A is shortened. As a result, the turnaround time for semiconductor integrated circuit devices is shortened.

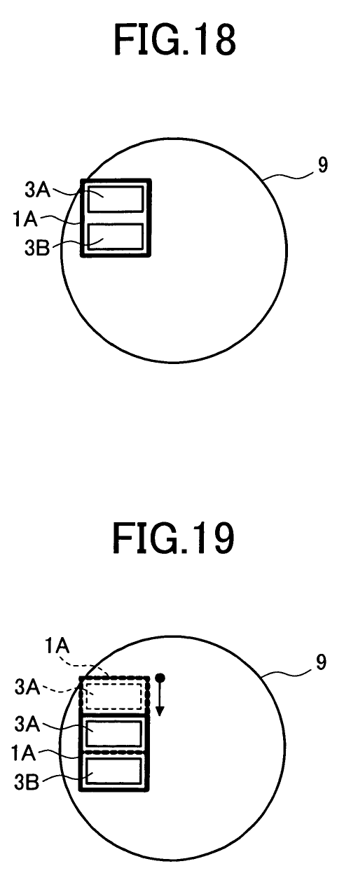

Next, an example of a method of multiple exposure through the mask 1A according to the first embodiment will be described referring to FIGS. 18 to 20. FIGS. 18 to 20 are plan views which schematically show a wafer 9 as a whole in various steps of multiple exposure. For example, the wafer 9 is a silicon-based discoid thin plate and a silicon oxide film with a thickness of 200 nm or so lies over its main surface (device formation surface). For example, a positive type photoresist film with a thickness of 300 nm or so is coated over the silicon oxide film. The exposure conditions which the inventors actually used are as follows. A scanner was used as a reduction projection exposure apparatus. As the light source for the scanner, an ArF excimer laser with a wavelength of 193 nm was used and the numerical aperture NA of the optical lens was 0.70. The shape of the scanner light source was circular (SHRINC, superhigh resolution by illumination control) and the coherent factor (σ) was 0.3. An exposure dose for the photoresist film was 150 J/m² so that double exposure corresponds to 300 J/m². An exposure dose is calculated by dividing the required amount of exposure by the number of exposures.

First, as illustrated in FIG. 18, a scanning exposure of the patterns in the exposure areas 3A and 3B of the mask 1A is made by the scanner. The amount of exposure here is about one half of the required amount of exposure. Then, the wafer 9 is moved up as illustrated in FIG. 19 and a scanning exposure of the patterns in the exposure areas 3A and 3B of the mask 1A is made by the scanner. The amount of movement of the wafer 9 is one half of the total exposure area so that the exposure area 3A of the mask 1A overlaps the transferred exposure area 3B on the photoresist film of the wafer (FIG. 18). The amount of exposure here is also about one half of the required amount of exposure. The required amount of exposure is thus obtained through double exposure of the exposure areas 3A and 3B.

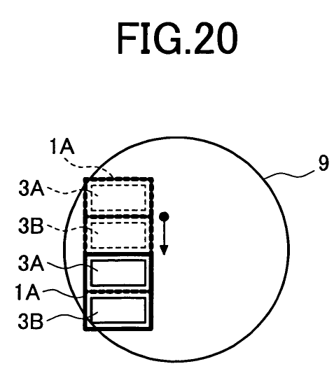

Next, the wafer 9 is moved up as illustrated in FIG. 20 and a scanning exposure of the patterns in the exposure areas 3A and 3B of the mask 1A is made by the scanner similarly. Again, the amount of movement of the wafer 9 is one half of the total exposure area so that the exposure area 3A of the mask 1A overlaps the transferred exposure area 3B on the photoresist film of the wafer (FIG. 19). Again, the amount of exposure here is about one half of the required amount of exposure. The required amount of exposure is obtained through double exposure of the exposure areas 3A and 3B. This multiple exposure operation is repeated all over the main surface of the wafer 9 so that line patterns are transferred onto plural chip areas of the main surface of the wafer 9. In the abovementioned process, some areas remain not double-exposed (for example, outmost chip areas of the main surface of the wafer 9). Actually, the above double exposure operation was performed with such areas shielded by masking blades.

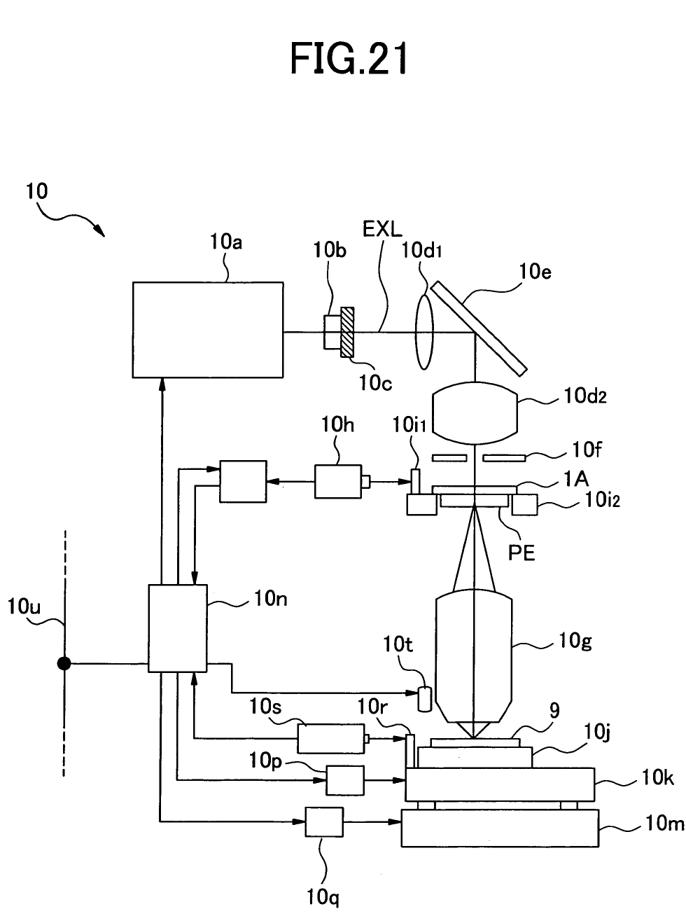

Next, the scanner will be described. FIG. 21 shows a scanner 10 as an example. The scanner 10 is, for example, a scanning reduction projection exposure apparatus with a reduction ratio of 4:1. The exposure conditions for the scanner 10 are as described above with reference to FIGS. 18 to 20.

Exposure light EXL from an exposure light source 10a passes through a fly-eye lens 10b, an illumination aperture 10c, condenser lenses 10d1, 10d2, and a mirror 10e and reaches and illuminates the mask (reticle) 1A. The coherent factor is adjusted by changing the size of the opening of an illumination aperture 10f. Pellicles PE are provided on the main surface (first surface) of the mask 1A in order to prevent pattern transfer failures due to adhesion of foreign matter. The mask pattern drawn on the mask 1A is projected through a projection lens 10g onto photoresist film over the main surface of the wafer 9 as a substrate. The mask 1A rests on a mask stage 10i2 which is controlled by a mask position controller 10h and a mirror 10il and its center is accurately aligned with the optical axis of the projection lens 10g. The mask 1A rests on the mask stage 10i2 with its main surface (first surface) facing the wafer 9. Exposure light EXL goes through the reverse surface of the mask 1A (second surface) to its main surface (first surface).

The wafer 9 is held on a wafer stage 10j by vacuum suction. The wafer stage 10j rests on a Z-stage 10k which is movable in the direction of the optical axis of the projection lens 10g, or vertically (z direction) to the wafer plane, and the Z-stage 10k rests on an XY-stage 10m which is movable in the direction parallel to the wafer plane on the wafer stage 10j. The Z-stage 10k and the XY-stage 10m are respectively driven by stage drive motors 10p and 10q according to control commands from a main control unit 10n so that they move to a desired exposure position. The position of a bar mirror 10r fixed on the Z-stage 10k, which represents their position, is accurately monitored by a laser measurement machine 10s. The surface position of the wafer 9 is measured by a focus position detector like one incorporated in an ordinary exposure apparatus. The Z-stage 10k is moved according to the measurement result so that the main surface of the wafer 9 is always in alignment with the imaging surface of the projection lens 10g.

The mask 1A and the wafer 9 are synchronously driven according to the reduction ratio and as the main surface of the mask 1A is scanned through the scanner's exposure area, the mask pattern is transferred onto the photoresist film over the main surface of the wafer 9 in reduced form. At this time, the position of the main surface of the wafer 9 is dynamically controlled by the above motors as the wafer 9 is scanned. When an exposure of a circuit pattern on the mask 1A is to be made over the transferred circuit pattern on the wafer 9, the position of a mark pattern on the wafer 9 is detected by an alignment detection optical system 10t and the position of the wafer 9 is determined depending on the result of detection, before double exposure. The main control unit 10n is electrically connected with a data network system 10u so that the condition of the scanner 10 can be remotely monitored.

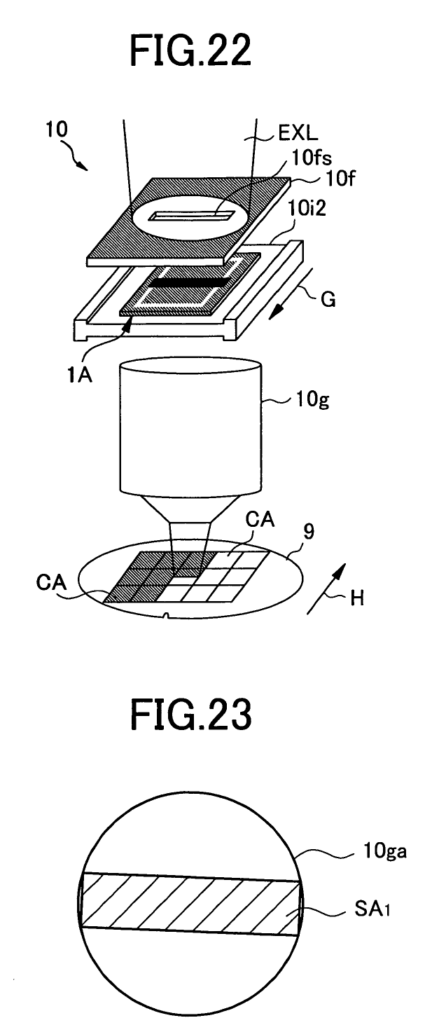

FIG. 22 schematically shows scanning exposure operation of the scanner 10 and FIG. 23 schematically shows an exposure area in the scanner 10. To facilitate understanding, FIGS. 22 and 23 include hatching.

In scanning exposure operation by the scanner 10, the mask 1A and the wafer 9 are moved in opposite directions while their main surfaces are kept parallel to each other. In other words, since the positional relation between the mask 1A and the wafer 9 is mirror symmetry, the scan direction for the mask 1A (arrow G) and the scan direction for the wafer 9 (arrow H) are opposite as shown in FIG. 22. The mask 1A is positioned in a way that its exposure areas 3A and 3B are arranged side by side along the scanner10's scan direction. For a reduction ratio of 4:1, the ratio of the amount of movement of the mask 1A to that of the wafer 9 is 4:1. Exposure light EXL passes through a flat rectangular exposure slit 10fs in the illumination aperture 10f and reaches and illuminates the mask 1A. This means that a slit exposure area (exposure band) SA1 included in an effective exposure area 10ga of the projection lens 10g is used as a practical exposure area. Typically the width (shorter side size) of the slit 10fs is in the range of 4-7 mm on the wafer 9, though not limited thereto. The slit exposure area SA1 is continuously moved (scanned) in the width (shorter side) direction of the slit 10fs (namely direction perpendicular or oblique to the longitudinal direction of the slit 10fs) so that exposure light passes through the imaging optical system (projection lens 10g) to reach and illuminate the main surface of the wafer 9. Consequently, an exposure of the mask pattern in the exposure areas 3A and 3B of the mask 1A (integrated circuit pattern; in the first embodiment, light-transmitting patterns 6a and 6b, or line patterns) is made in each of plural chip areas CA of the wafer 9. Only specific components of the scanner 10 are shown here to describe the scanner's functionality. The other components of the scanner are similar to those used in an ordinary scanner.

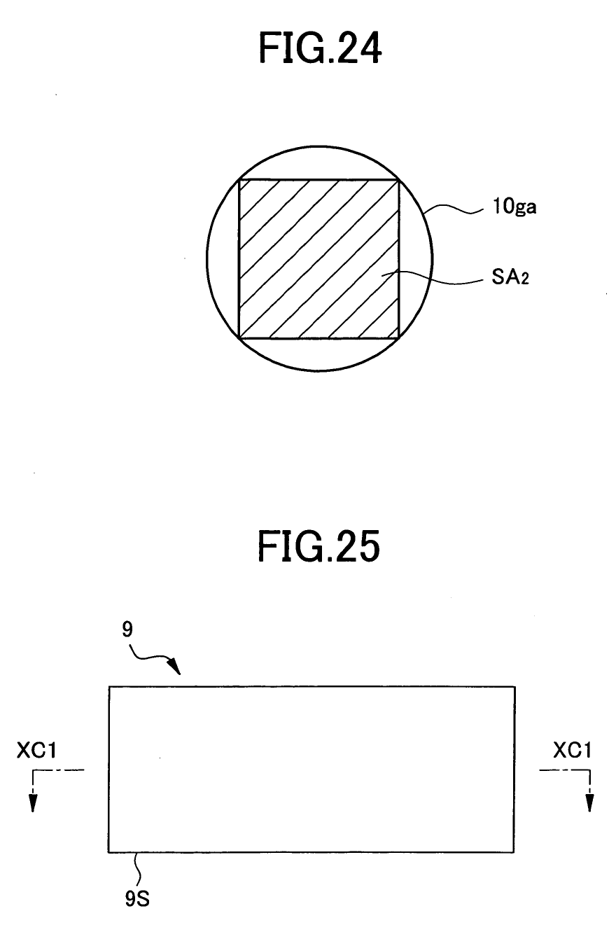

FIG. 24 shows an exposure area SA2 (hatched for easy understanding) in case that a stepper is used. In a stepper, after one shot or exposure (for one or more chips) is finished, the stage is moved to the next shot position and the same exposure operation is done again. This sequence is repeated until the whole wafer main surface is exposed. In the case of a stepper, a flat square exposure area SA2 in the effective exposure area 10ga of the projection lens 10g is used as a practical exposure area. The four corners of this exposure area SA2 are inscribed in the effective exposure area 10ga. In the first embodiment, a stepper may be used as an exposure apparatus. However, generally it is difficult to make patterns properly as designed through multiple exposure by a stepper because the projection lens 10g has various aberrations. On the other hand, when the scanner 10 is used for exposure, although a positional error may occur due to lens aberration in the direction perpendicular to the scan direction, lens aberration in the scan direction is equal and thus the same shape is maintained. The first embodiment takes advantage of this feature of the scanner; when the scanner is used, the patterns in the exposure areas 3A and 3B to be transferred are deformed almost equally in the direction perpendicular to the scan direction and formed into almost equal shapes. This is because the exposure areas 3A and 3B for double exposure are arranged side by side along the scan direction. Therefore, patterns are transferred with high alignment accuracy even through double exposure.

A method of manufacturing a semiconductor device by the use of the mask 1A will be explained below.

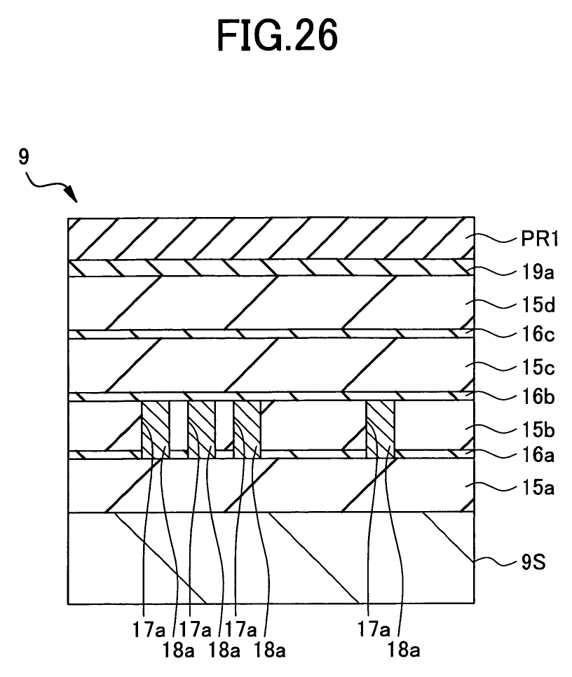

FIG. 25 is a plan view of the key part of the wafer 9 in the process of manufacturing a semiconductor device according to the first embodiment and FIG. 26 is a sectional view taken along the line XC1-XC1 of FIG. 25. The substrate 9S of the wafer 9 is, for example, made of p-type silicon monocrystal and active elements such as a p-channel MOS FET (Metal Oxide Semiconductor Field Effect Transistor) and an n-channel MOS FET, and a passive element such as a resistor are formed in each chip area of its main surface. The p-channel MOS FET and n-channel MOS FET constitute a CMOS (complementary MOS) circuit, leading to a logical circuit. For example, insulating films of silicon oxide (SiO₂, etc) 15a to 15d and thinner insulating films of silicon nitride (Si₃N₄, etc) are stacked alternately over the main surface of the wafer 9. Wiring slits (wiring openings) 17a are made in the insulating films 15b and 16a and a first layer of buried wiring 18a (single damascene wiring) is made in the wiring slits 17a. The main material for the buried wiring 18a is, for example, tungsten and for example, thin barrier coatings of titanium nitride (TiN) are made on its sides and bottom. An anti-reflective coating 19a and a positive type photoresist film PR1 are stacked over the insulating film 15d in the order of mention.

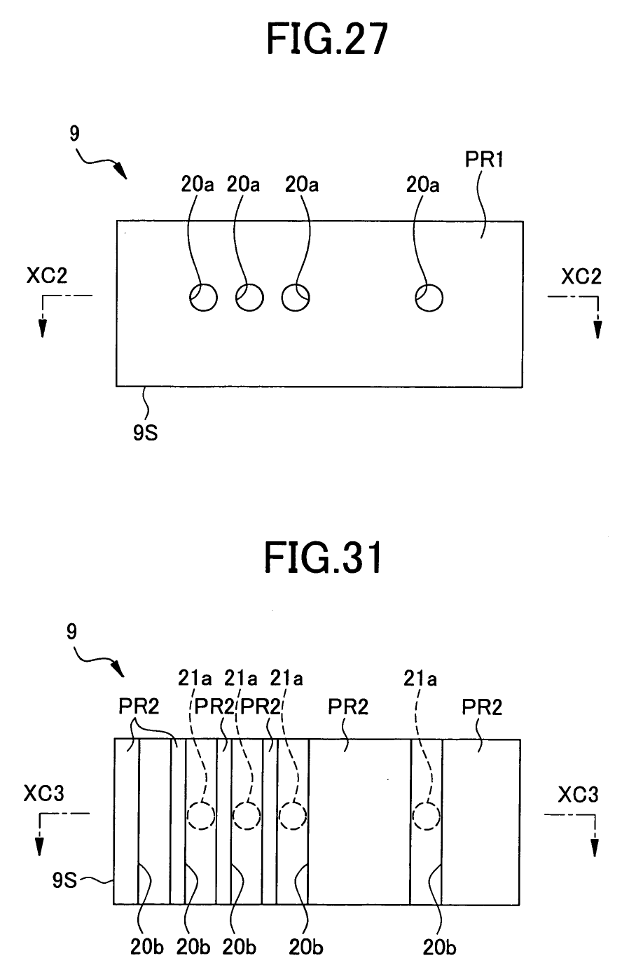

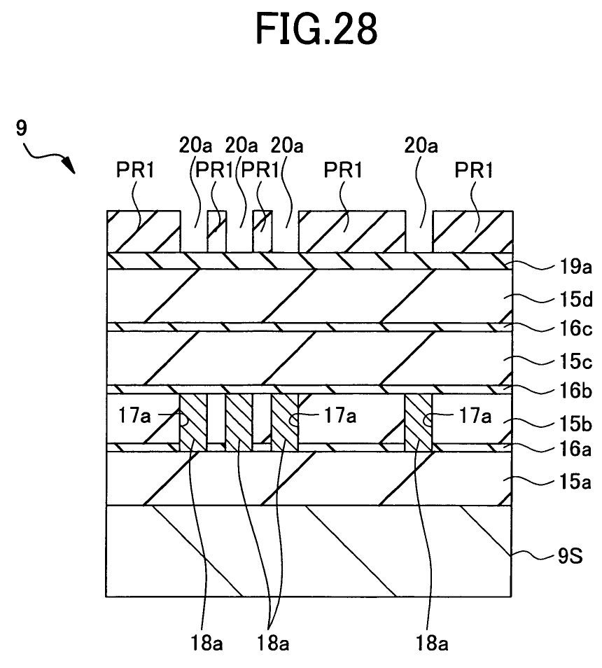

First, after the photoresist film PR1 of the wafer 9 as mentioned above is exposed using a mask, the film is developed. As a result, a pattern of photoresist film PR1 having openings 20a for hole patterns appears as illustrated in FIGS. 27 and 28. FIG. 27 is a plan view of the key part of the wafer 9 in a step of the semiconductor device manufacturing process which is next to the steps shown in FIGS. 25 and 26 and FIG. 28 is a sectional view taken along the line XC2-XC2 of FIG. 27.

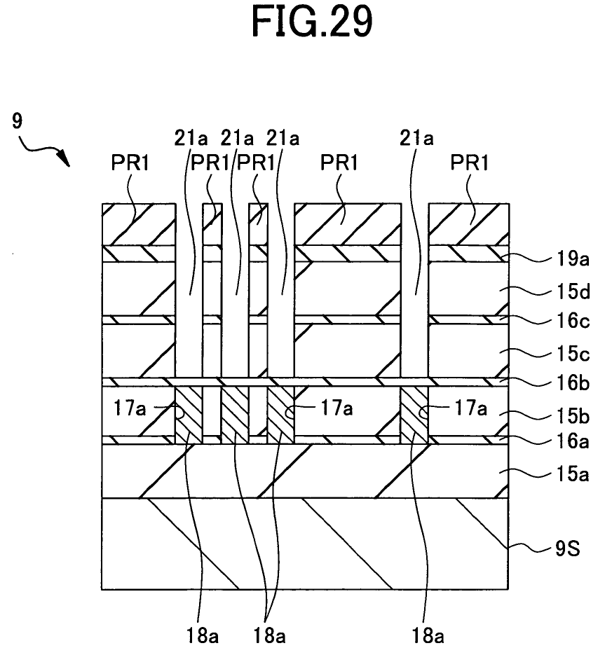

Next, this photoresist film PR1 pattern is used as an etching mask to etch the anti-reflective coating 19a, insulating films 15d, 16c and 15c in the openings 20a in the order of mention so that through holes 21a are made as illustrated in FIG. 29. This etching process is done in a manner that the insulating film 16b at the bottoms of the through holes 21a functions as an etch stopper. This means that in this step, the insulating film 16b remains at the bottoms of the through holes 21a. FIG. 29 is a sectional view of the key part of the wafer 9 in a step of the semiconductor device manufacturing process which is next to the steps shown in FIGS. 27 and 28.

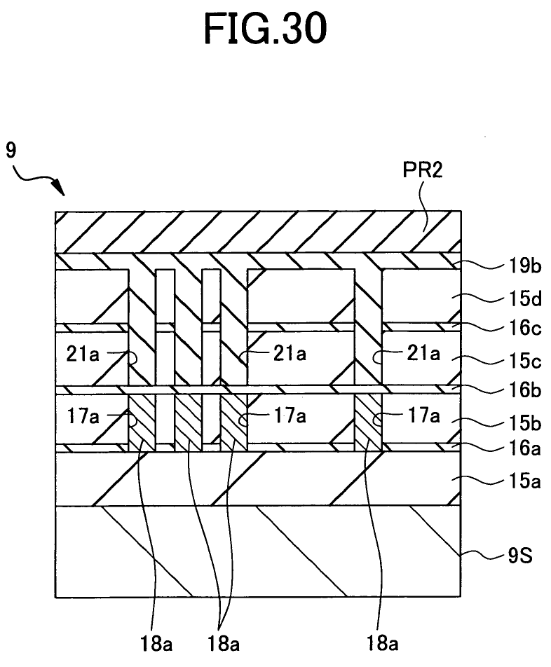

Then, after the photoresist film PR1 and the anti-reflective coating 19a are removed, another anti-reflective coating 19b is buried in the through holes 21a over the main surface of the wafer 9, as illustrated in FIG. 30. Further, a positive type photoresist film PR2 is coated over the anti-reflective coating 19b. FIG. 30 is a sectional view of the key part of the wafer 9 in a step of the semiconductor device manufacturing process which is next to the step shown in FIG. 29.

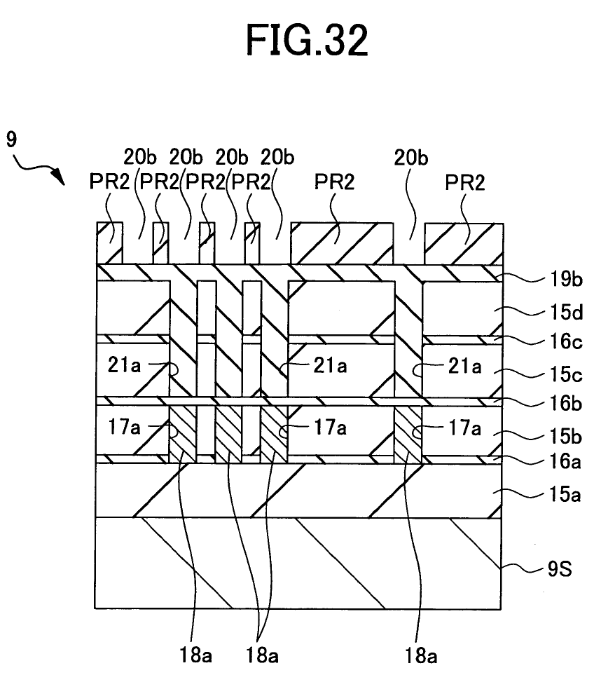

Next, after the photoresist film PR2 is exposed using the mask 1A, the film is developed. As a result, a pattern of photoresist film PR2 having openings 20b for line patterns appears as illustrated in FIGS. 31 and 32. The exposure apparatus and exposure conditions used here are the same as mentioned above. FIG. 31 is a plan view of the key part of the wafer 9 in a step of the semiconductor device manufacturing process which is next to the step shown in FIG. 30; and FIG. 32 is a sectional view taken along the line XC3-XC3 of FIG. 31.

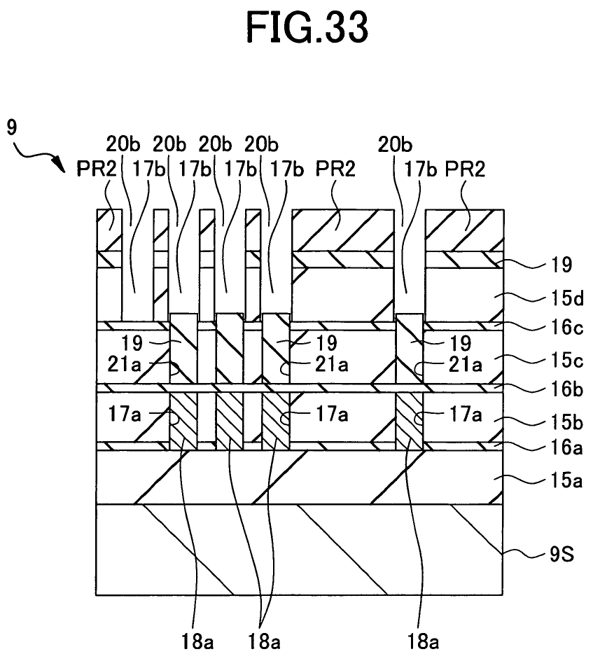

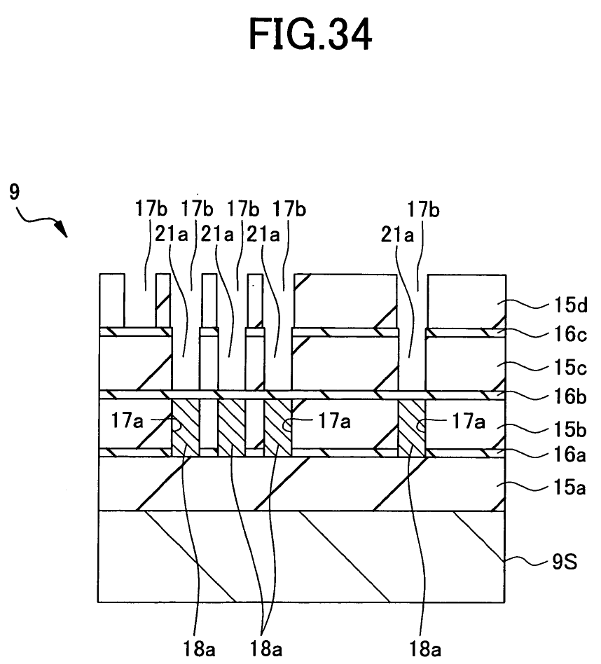

Next, this photoresist film PR2 pattern is used as an etching mask to etch the anti-reflective coating 19b and insulating film 15d in the openings 20b in the order of mention so that wiring slits (wiring openings) 17b are made as illustrated in FIG. 33. This etching process is done in a manner that the insulating film 16c at the bottoms of the wiring slits 17b functions as an etch stopper. This means that in this step, the insulating film 16c remains at the bottoms of the wiring slits 17b. Then, after the photoresist film PR2 and the anti-reflective coating 19b are removed as illustrated in FIG. 34, the insulating films 16c and 16b at the bottoms of the wiring slits 17b and through holes 21a are selectively removed by wet etching with thermal phosphoric acid or the like so that through holes 21a and wiring slits 17b are completed as illustrated in FIG. 35 (dual damascene process). Consequently, the top surface of the buried wiring 18a is partially exposed in the bottoms of the through holes 21a. FIG. 33 is a sectional view of the key part of the wafer 9 in a step of the semiconductor device manufacturing process which is next to the steps shown in FIGS. 31 and 32; FIG. 34 is a sectional view of the key part of the wafer 9 in a step of the semiconductor device manufacturing process which is next to the step shown in FIG. 33; and FIG. 35 is a sectional view of the key part of the wafer 9 in a step of the semiconductor device manufacturing process which is next to the step shown in FIG. 34.

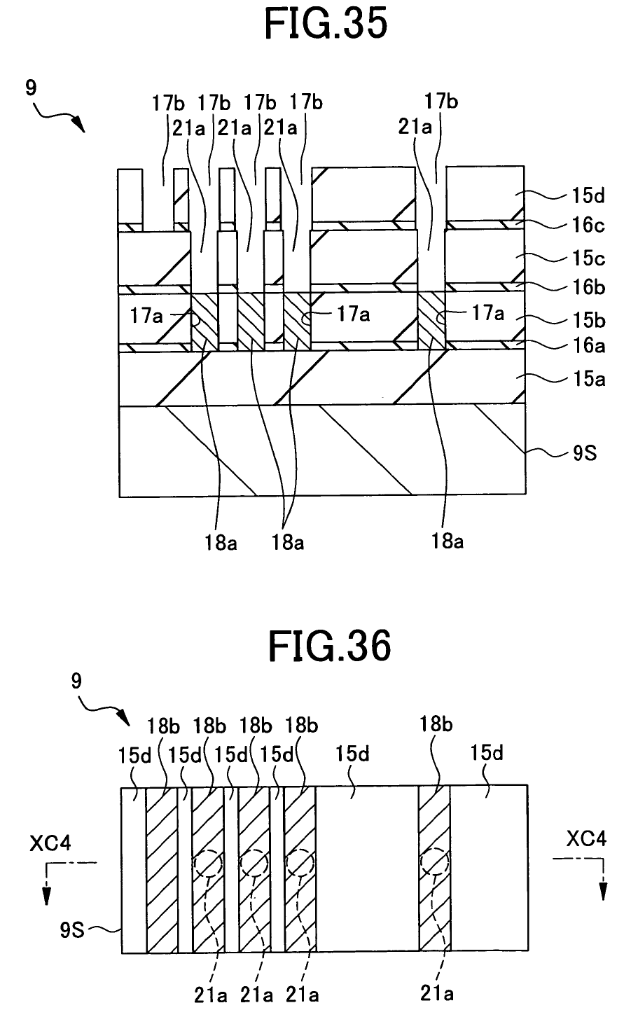

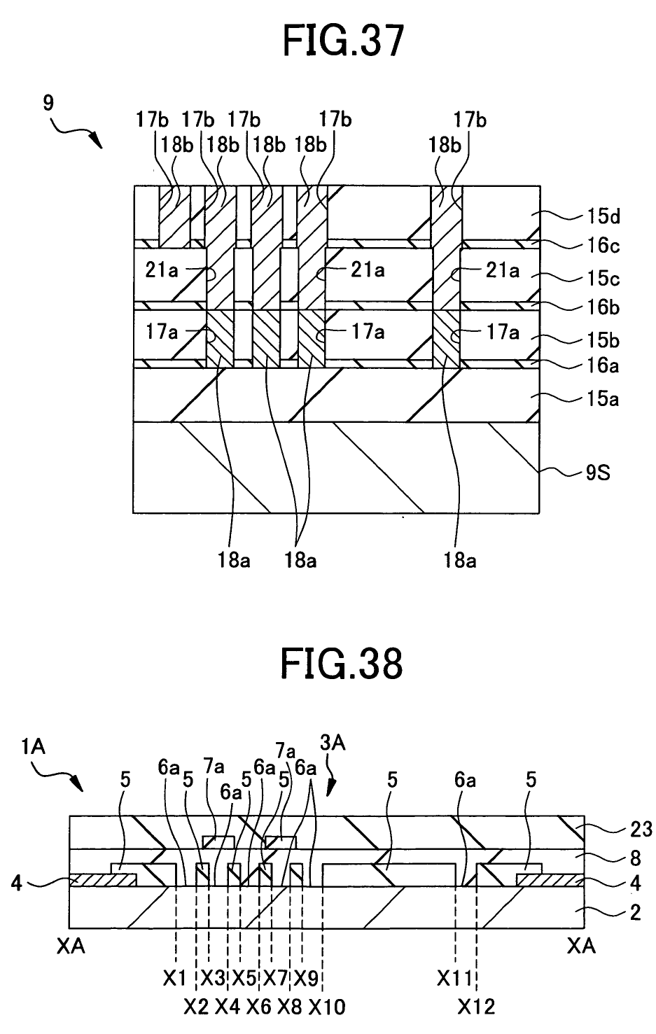

Next, a thin barrier coating of tantalum (Ta), tantalum nitride (TaN) or titanium nitride (TiN) is made over the main surface of the wafer 9 by sputtering or a similar technique; then a thicker coating of main wiring material (for example, Cu) is made by plating or CVD. After this, the laminate of these coatings is polished by chemical mechanical polishing (CMP) or a similar technique. In this process, unwanted parts of the laminate of main wiring material and barrier coating around the wiring slits 17b are removed until the laminate remains only in the wiring slits 17b and through holes 21a. In this way, a second layer of buried wiring 18b (dual damascene wiring) is formed in the wiring slits 17b as illustrated in FIGS. 36 and 37. FIG. 36 is a plan view of the key part of the wafer 9 in a step of the semiconductor device manufacturing process which is next to the step shown in FIG. 35; and FIG. 37 is a sectional view taken along the line XC4-XC4 of FIG. 36.

Thus, according to the first embodiment, a semiconductor device with a logical circuit of 65 nm node wiring width (for example, 70-90 nm) can be manufactured using an ArF excimer laser as an exposure light source.

### Second Embodiment

Given below is a description of the second embodiment in which a film which intercepts oxygen covers shifters after formation of the shifters for the purpose of improving the resistance to exposure light of the shifters made of resist film.

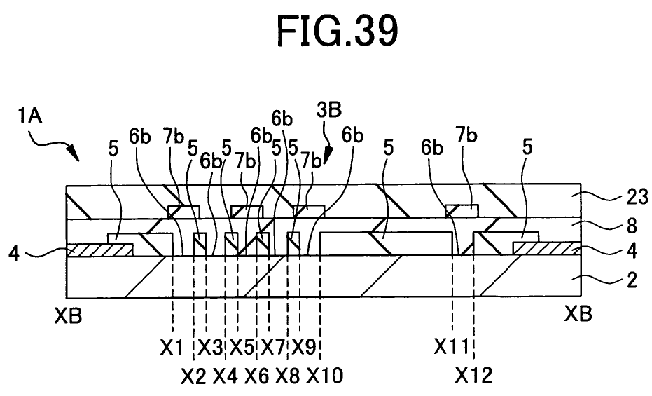

FIGS. 38 and 39 show a mask 1A according to the second embodiment, where FIG. 38 is a sectional view taken along the line XA-XA of FIG. 1 and FIG. 39 is a sectional view taken along the line XB-XB of FIG. 1. A film which intercepts oxygen 23 is made over the planarizing film 8 so as to cover the shifters 7a and 7b. The material and characteristics (thickness, exposure light transmittance, oxygen interception rate, flatness and so on) of the oxygen-intercepting film 23 and the formation method thereof are the same as those of the planarizing film 8 (mentioned above). The top surface of the oxygen-intercepting film 23 is also flat as shown in these figures, though it need not be flat. The purpose is achieved by lowering the oxygen concentration insofar as exposure does not cause chemical reaction between the resist film and oxygen.

According to the second embodiment, the oxygen-intercepting film 23 reduces or prevents reaction between the shifters 7a or 7b and oxygen during exposure which might cause etching (thinning) of them. In short, it improves the light resistance of the shifters 7a and 7b. Hence, according to the second embodiment, although patterns are transferred properly without multiple exposure as explained above in connection with the first embodiment, multiple exposure offers the same effects as in the first embodiment.

So far, preferred embodiments of the invention made by the inventors have been concretely described. However, obviously the present invention is not limited to the above embodiments but may be embodied in other various forms without departing from the scope and spirit thereof.

For example, the above descriptions of the first and second embodiments assume that double exposure is made; however, the present invention is not limited thereto. Three, four or more exposures may be made in a chip area. Since embodiments of the invention use phase-shifting masks, it is desirable to make an even number of exposures, taking phase inversion into consideration. In other words, as the number of exposures in a chip area increases, pattern defects can be reduced or removed and thus disconnections or short-circuiting can be minimized or eliminated, thereby reducing or eliminating the possibility of disconnection or short-circuiting.

The above descriptions of the first and second embodiments assume that photoresist patterns are formed for use in etching an insulating film or conductor film. However, the present invention is not limited thereto. The invention is applied to a case of making a photoresist pattern which is used as a mask for introducing impurities into a wafer.

For an exposure light source, it is also possible to use i rays with an exposure wavelength of 365 nm or a KrF excimer laser with an exposure wavelength of 248 nm or an F₂ excimer laser with an exposure wavelength of 157 nm.

For SHRINC or superhigh resolution by illumination control (illumination is controlled to lower the central illuminance) of an exposure light source, for example, oblique illumination or multi-pole illumination (for example, four-pole illumination, or five-pole illumination) may be used. Also, superhigh resolution technology with a pupil filter equivalent to SHRINC may be used instead.

The above description of the first embodiment assumes that it is applied to a damascene wiring process. However, the present invention is not limited thereto. The present invention can be applied to a case that wiring patterns are made by patterning a conductor film. In this case, a negative type photoresist film is formed over the conductor film and patterns are transferred by making multiple exposure as mentioned above on the negative type photoresist film.

The above descriptions of the first and second embodiments assume that the wafer is a semiconductor wafer which uses silicon for the substrate. However, the present invention is not limited thereto. The wafer may use a sapphire, glass or other insulating, semi-insulating or semiconductor substrate or a combination of these.

Semiconductor devices to which the present invention is applicable include not only ones which use silicon wafers or semiconductor substrates such as sapphire substrates or insulating substrates but also ones which use glass or other insulating substrates, such as TFT (Thin Film Transistor) and STN (Super-Twisted-Nematic) liquid crystal, unless otherwise specified.

The above explanation focuses application of the invention to semiconductor device manufacturing processes which are in the field of utilization of the invention. However, the present invention is not limited thereto. For example, it may be applied to processes of manufacturing articles other than semiconductor devices, like liquid crystal display apparatuses or micromachines.

The present invention can be applied to manufacturing industries for products which require microfabrication.

1. A semiconductor device manufacturing method comprising the steps of:
(a) making a photoresist film over a main surface of a wafer; and
(b) transferring a desired pattern on the photoresist film by reduction projection exposure on the wafer through a mask,
the mask including:
mask blanks having a first surface and a second surface on its reverse;
shading material of resist formed on the first surface of the mask blanks;
light-transmitting areas as openings in the shading material of resist;
a planarizing film formed on the first surface of the mask blanks so as to cover the shading material of resist; and
phase shifters of resist formed on the planarizing film,
wherein the planarizing film is buried in openings in the shading material of resist to form the light-transmitting areas so that a phase error in light which passes through the light-transmitting areas is within a tolerance.

2. The semiconductor device manufacturing method as claimed in claim 1, wherein the planarizing film has a function of minimizing or preventing deterioration of the shading material of resist.

3. The semiconductor device manufacturing method as claimed in claim 1,
wherein the step (b) includes making double exposure with a first exposure area and a second exposure area of the mask in one area of the photoresist film over the main surface of the wafer; and
wherein the light-transmitting areas in the first exposure area and the second exposure area are equal in shape, size, and arrangement; and
wherein the phase shifters in the first exposure area and the second exposure area are arranged alternately.

4. The semiconductor device manufacturing method as claimed in claim 3, wherein the first exposure area and the second exposure area lie on the same main surface of the same mask.

5. The semiconductor device manufacturing method as claimed in claim 3, wherein the reduction projection exposure process is scanning exposure.

6. The semiconductor device manufacturing method as claimed in claim 5, wherein the first exposure area and the second exposure area lie on the same main surface of the same mask and in the reduction projection exposure process, scanning exposure is done while the mask is positioned so that the first exposure area and the second exposure area are arranged side by side along the direction of scanning exposure.

7. The semiconductor device manufacturing method as claimed in claim 3, wherein an exposure dose for one area of the photoresist film in the reduction projection exposure process is calculated by dividing the required amount of exposure by the number of exposures.

8. A semiconductor device manufacturing method comprising the steps of:
(a) making a photoresist film over a main surface of a wafer; and
(b) transferring a desired pattern on the photoresist film by reduction projection exposure on the wafer through a mask,
the mask including:
mask blanks having a first surface and a second surface on its reverse;
shading material of resist formed on the first surface of the mask blanks;
light-transmitting areas as openings in the shading material of resist;
a planarizing film formed on the first surface of the mask blanks so as to cover the shading material of resist; and
phase shifters of resist formed on the planarizing film,
wherein the planarizing film is buried in openings in the shading material of resist to form the light-transmitting areas so that a phase error in light which passes through the light-transmitting areas is within a tolerance; and
wherein the step (b) includes making double exposure with a first exposure area and a second exposure area of the mask in one area of the photoresist film over the main surface of the wafer; and
wherein the light-transmitting areas in the first exposure area and the second exposure area are equal in shape, size, and arrangement; and
wherein the phase shifters in the first exposure area and the second exposure area are arranged alternately.

9. The semiconductor device manufacturing method as claimed in claim 8, wherein the planarizing film has a function of minimizing or preventing deterioration of the shading material of resist.
